(19) United States
(12) Patent Application Publication
(10) Pub. No.: US 2010/0061418 A1
(43) Pub. Date: Mar. 11, 2010

(54) Mounting surface-emitting devices

(76) Inventors: John Douglas Lambkin, Carrigaline (IE); David Antony Barrow, Kinsale (IE); Yoshihiro Someno, Miyagi pri (JP)

Correspondence Address: JACOBSON HOLMAN PLLC, 400 SEVENTH STREET N.W., SUITE 600, WASHINGTON, DC, 20004, US

(21) Appl. No.: 12/309,174

(22) PCT Filed: Jul. 5, 2007
(86) PCT No.: PCT/GB2007/002512

§ 371 Date: Nov. 4, 2009

(30) Foreign Application Priority Data
Jul. 11, 2006 (GB) 0613714.5

(51) Int. Cl. H01S 5/18; H01L 33/00; H01L 21/50

(52) U.S. Cl. 372/50.23; 257/98; 438/27; 257/E33.067; 257/E21.499

(57) ABSTRACT

An optical emitter assembly is described in which one or more optical devices each having an emitting aperture at a surface thereof can be mounted on a carrier such that the plane of the emitting apertures with respect to a well defined reference plane can be precisely controlled. This enables additional optical elements to be precisely axially and laterally positioned with respect to the centre of the emitting apertures, even when there are plural optical devices of differing thicknesses. The assembly may comprise a surface-emitting optical device having an emission surface providing an optical output aperture; a carrier having first and second opposing surfaces, the first surface being a reference surface on which the optical device is mounted by its emission surface and the second surface being a back surface, the carrier having an aperture extending between the reference and back surfaces, the optical device being positioned on the reference surface such that its optical output aperture is in overlying relation with the carrier aperture to direct optical radiation therethrough.

The present invention relates to the mounting of surface-emitting light sources and the mounting of arrays of surface-emitting light sources.

Surface-emitting optical devices such as vertical cavity surface-emitting lasers (VCSELs) and surface-emitting light emitting diodes (LEDs) are extensively used in a wide variety of applications. However, such LEDs and lasers are being used in an increasing number of sensing and imaging applications where the active light source is an integral part of an optical sub-system in which the physical position of the emitting aperture in relation to other optical elements within the sub-system must be controlled to high precision, both longitudinally and laterally, to enable the sub-system to operate within target specification.

For a top-emitting device the position of the emitting aperture in relation to a well defined reference plane in the sub-assembly, such as the surface of the LED or laser sub-mount, will depend upon the thickness of the device chip. The thickness of the chip is normally determined by a wafer lapping process which can typically achieve a given specified thickness to within an uncertainty of ±10 μm. In some high precision optical arrangements this uncertainty in the position of the emitting aperture to a given optical reference plane, such as the laser mount surface, is unacceptable. This problem is further exacerbated when it is necessary to create an array of discrete devices which are derived from different manufacturing processes.

In addition, in an optical sub-assembly containing a surface-emitting device it is often necessary to position an optical element such as an aperture or lens whose optical axis must be in line with the emitting aperture of the optical device to a high level of precision to enable the sub-assembly to function within specification.

A method of mounting an optical device, a monolithic array of devices or an array of discrete devices is therefore revealed that removes the high level of uncertainty in the separation of the plane of the device's emitting aperture with respect to a well defined reference plane within the optical sub-assembly and in addition allows additional optical elements to be axially positioned with respect to the centre of the optical device's emitting aperture.

An object of the invention is to provide surface-emitting devices, monolithic device arrays and arrays of discrete devices which have a high registration accuracy of the planes of the optical emitting apertures relative to a well-defined reference plane in an optical sub-assembly.

A further object of the invention is to enable high precision alignment between the optical aperture of an emitting device and other optical elements in an optical sub-assembly.

According to one aspect, the present invention provides an optical emitter assembly comprising:
a surface-emitting optical device having an emission surface providing an optical output aperture;
a carrier having first and second opposing surfaces, the first surface being a reference surface on which the optical device is mounted by its emission surface and the second surface being a back surface, the carrier having an aperture extending between the reference and back surfaces;
the optical device being positioned on the reference surface such that its optical output aperture is in overlying relation with the carrier aperture to direct optical radiation therethrough.

According to another aspect, the present invention provides optical emitter assembly comprising:
at least two surface-emitting optical devices each having an emission surface providing an optical output aperture;
a carrier having first and second opposing surfaces, the first surface being a reference surface on which the optical devices are mounted by their respective emission surfaces and the second surface being a back surface, the carrier having an optical transmission path extending between the reference and back surfaces suitable for transmission of optical radiation from the optical devices;
at least one additional optical element disposed on the back surface of the carrier, the optical devices being positioned on the reference surface such that their optical output apertures are in overlying relation with a respective additional optical element such that the respective additional optical element is in the optical paths of optical emissions from the optical devices.

According to another aspect, the present invention provides an optical emitter assembly comprising:
a surface-emitting optical device having an emission surface providing an optical output aperture and a back surface opposite to the emission surface;
a carrier having a reference surface on which the optical device is mounted by its back surface;
an additional optical element for conditioning the optical output of the optical device, the additional optical element being mounted on or formed in an optical sub-unit,
the optical sub-unit being mounted on the reference surface such that the additional optical element is in overlying relation with the optical output aperture of the optical device so as to receive optical radiation therefrom.

According to another aspect, the present invention provides a method of mounting a surface-emitting optical device onto a carrier, the optical device having an emission surface providing an optical output aperture, comprising the steps of: forming a carrier having first and second opposing surfaces, the first surface being a reference surface on which the optical device is to be mounted and the second surface being a back surface opposite thereto;
forming a carrier aperture extending between the reference and back surfaces;
bonding the optical device by its emission surface to the reference surface of the carrier such that its optical output aperture is in overlying relation with the carrier aperture to direct Optical radiation therethrough.

According to another aspect, the present invention provides a method of mounting surface-emitting optical devices onto a carrier, the optical devices each having an emission surface providing an optical output aperture and a back surface opposite to the emission surface, comprising the steps of:
forming a carrier having first and second opposing surfaces, the first surface being a reference surface on which the optical devices are to be mounted and the second surface being a back surface, the carrier having an optical transmission path extending between the reference and back surfaces suitable for transmission of optical radiation from the optical devices and the carrier including an additional optical element for conditioning the output of the optical devices;
bonding the optical devices by their respective emission surfaces to the reference surface of the carrier, the optical devices being positioned on the reference surface such that their optical output apertures are in overlying relation with a respective additional optical element such that the respective additional optical element is in the optical paths of optical emissions from the optical devices.

According to another aspect, the present invention provides a method of mounting a surface-emitting optical device onto a carrier, the optical device having an emission surface providing an optical output aperture and a back surface opposite to the emission surface, comprising the steps of:
forming a carrier having a reference surface;
bonding the optical device, by its back surface, to the reference surface;
forming an additional optical element in or on an optical sub-unit, for conditioning the optical output of the optical device;
mounting the optical sub-unit onto the reference surface such that the additional optical element is in overlying relation with the optical output aperture of the optical device so as to receive optical radiation therefrom.

Embodiments of the present invention will now be described by way of example and with reference to the accompanying drawings in which:

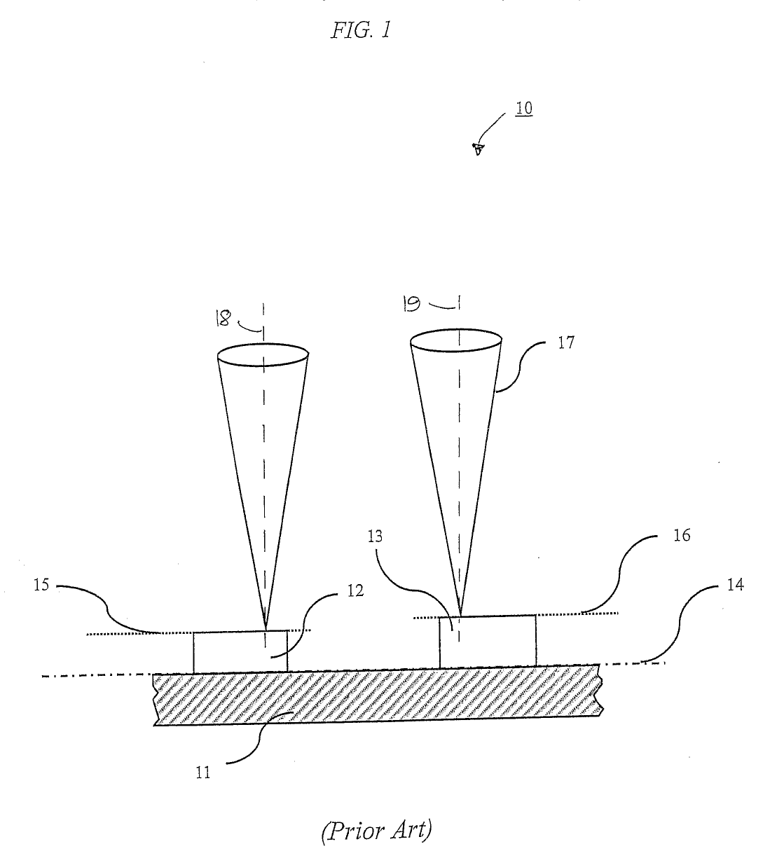

FIG. 1 is a schematic cross-sectional view of a prior art method of mounting a top-emitting laser or LED to a carrier;

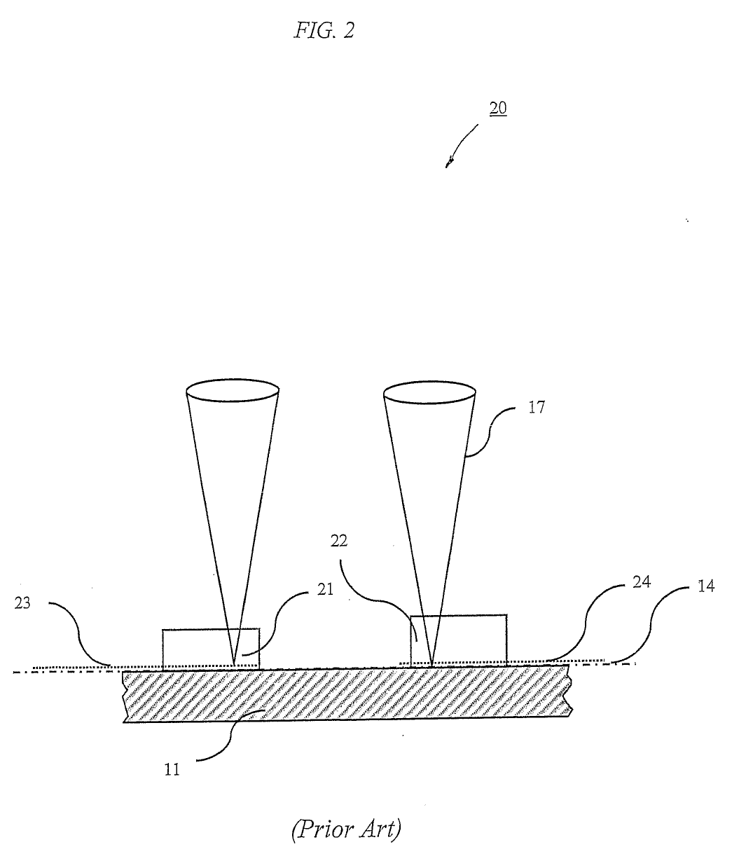

FIG. 2 is a schematic cross-sectional view of a prior art method of mounting a bottom-emitting (substrate-emitting) laser or LED to a carrier;

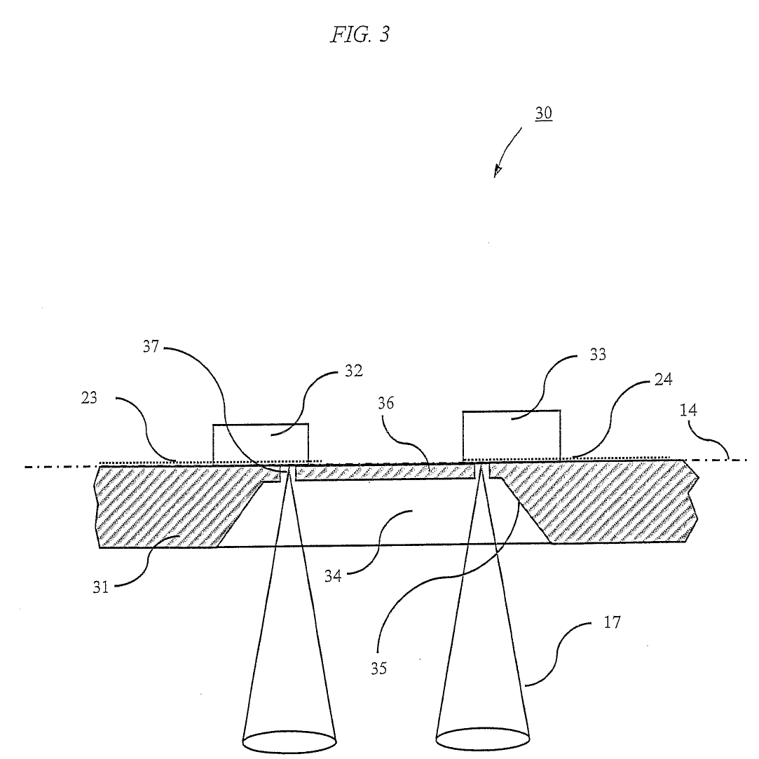

FIG. 3 is a schematic cross-sectional view of a pair of surface-emitting optical devices mounted on a carrier in inverted configuration so that emitted light passes through an aperture in the carrier;

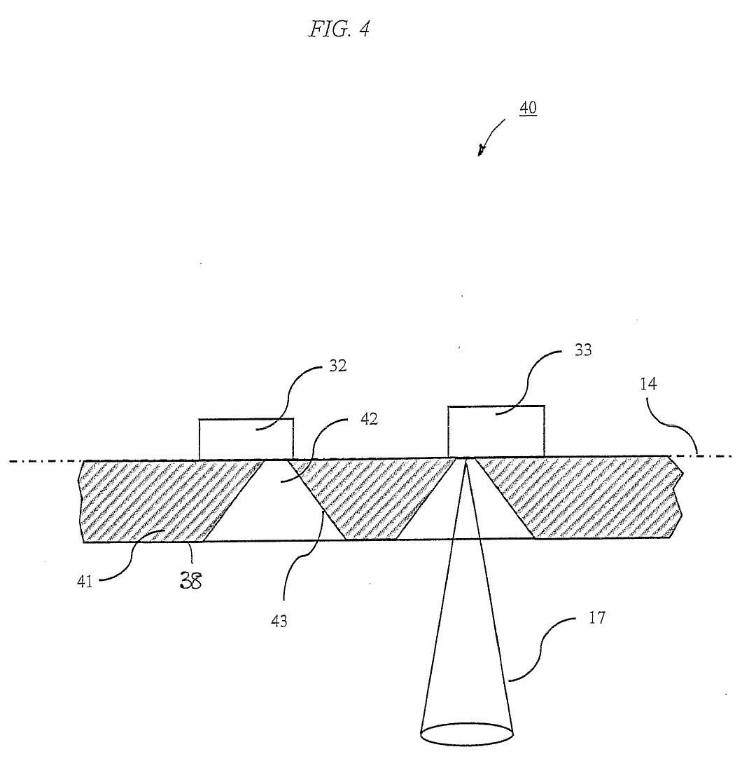

FIG. 4 is a schematic cross-sectional view of a pair of surface-emitting optical devices mounted on a carrier in inverted configuration so that emitted light passes through respective apertures in the carrier;

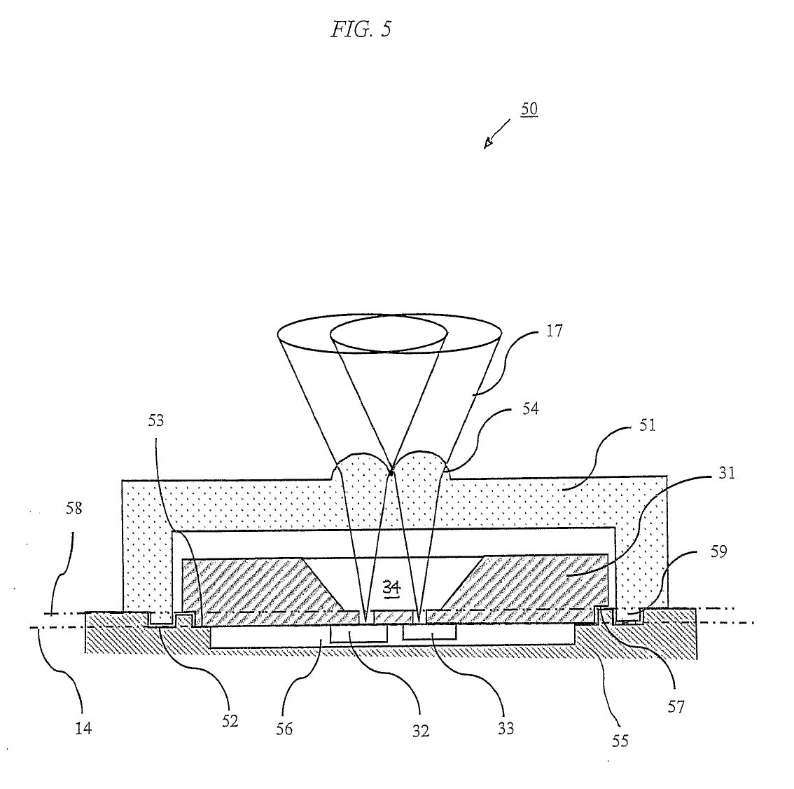

FIG. 5 is a schematic cross-sectional view of the assembly of FIG. 3 incorporated within a larger assembly including a lens array aligned, axially and longitudinally, to the emitting apertures of the surface-emitting optical devices;

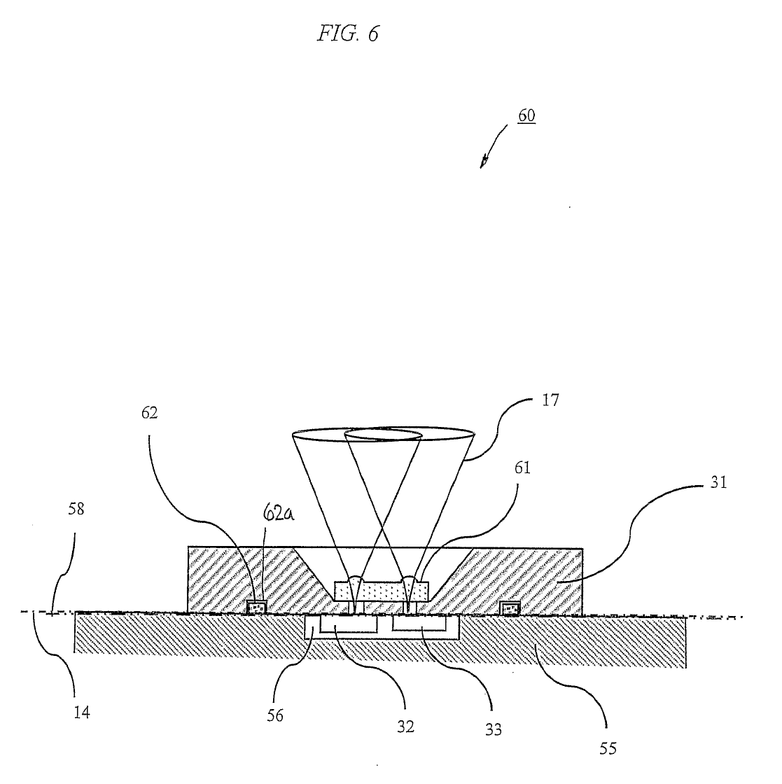

FIG. 6 is a schematic cross-sectional view of an alternative arrangement to that of FIG. 5;

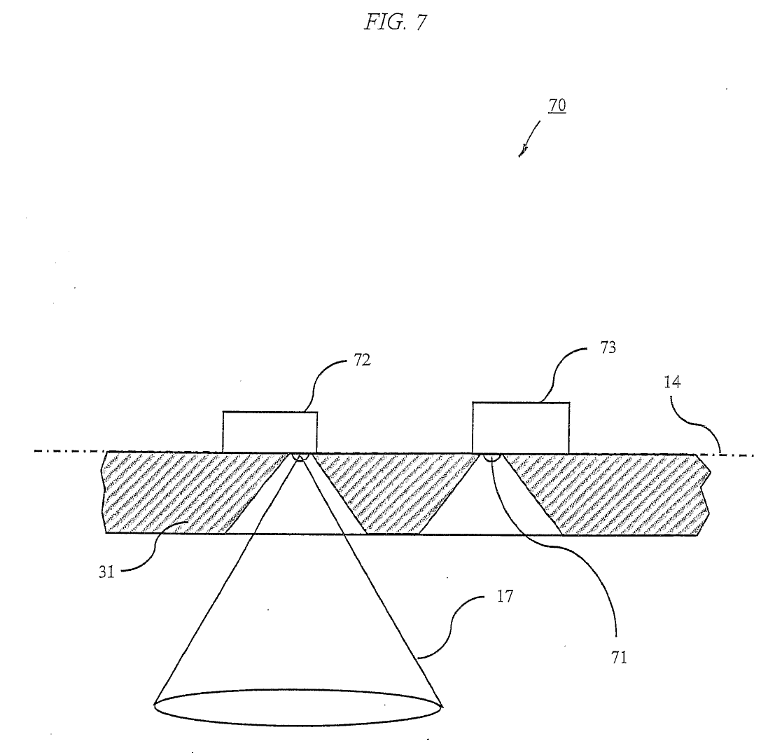

FIG. 7 is a schematic cross-sectional view of a pair of surface-emitting optical devices, each with integral lenses, mounted on a carrier in inverted configuration so that emitted light passes through respective apertures in the carrier;

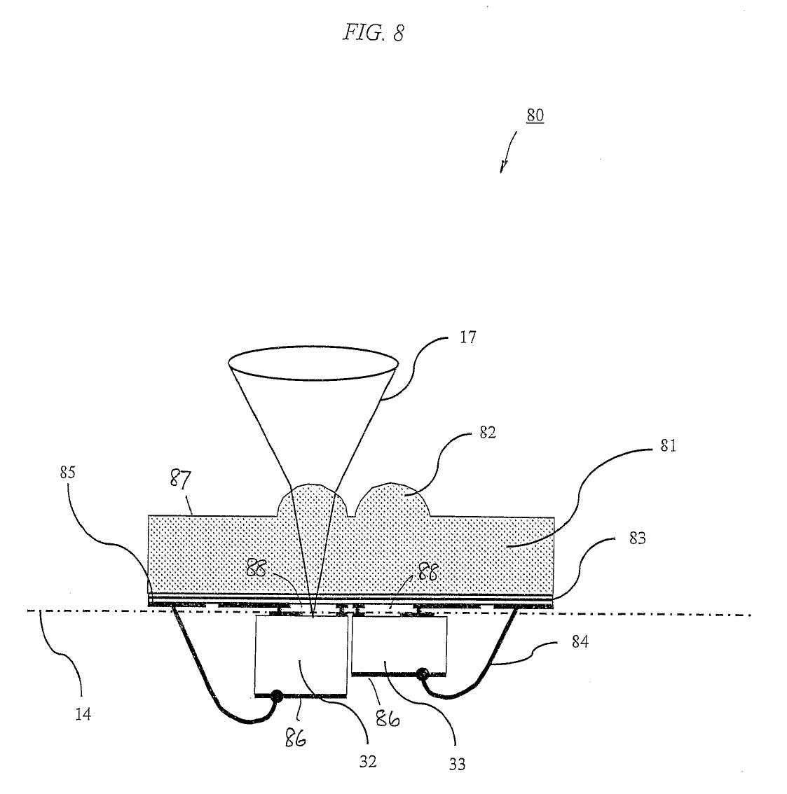

FIG. 8 is a schematic cross-sectional view of an alternative arrangement to that of FIG. 6 in which the carrier material is formed of transparent material and the lens array is incorporated into the carrier;

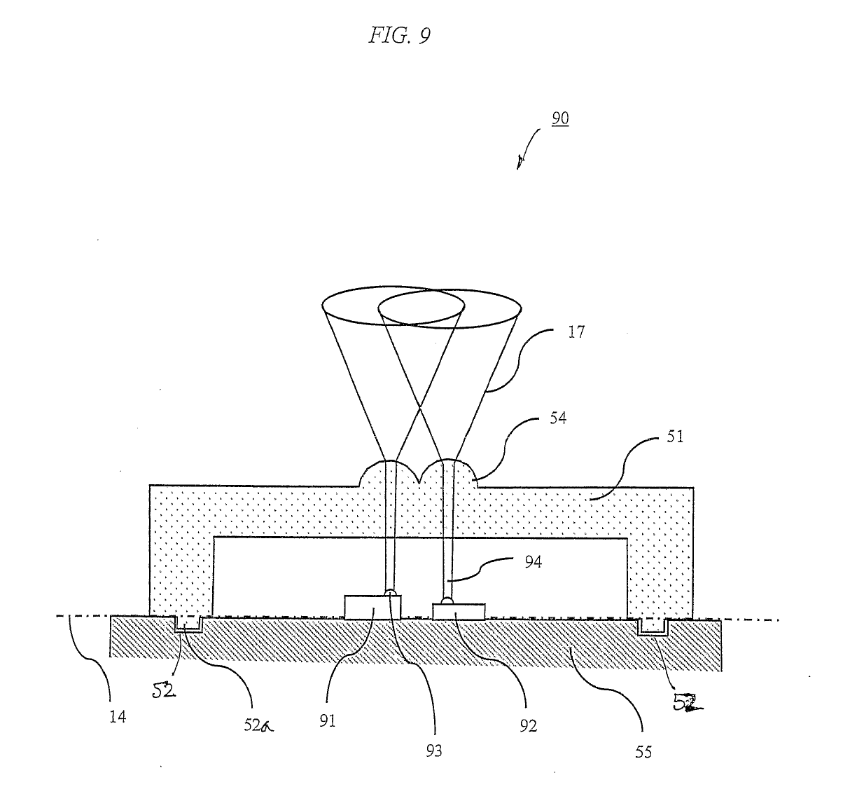

FIG. 9 is a schematic cross-sectional view of an alternative arrangement to that of FIG. 5 in which additional optical elements are formed on an optical sub-unit mounted on the same reference surface as the surface emitting optical devices;

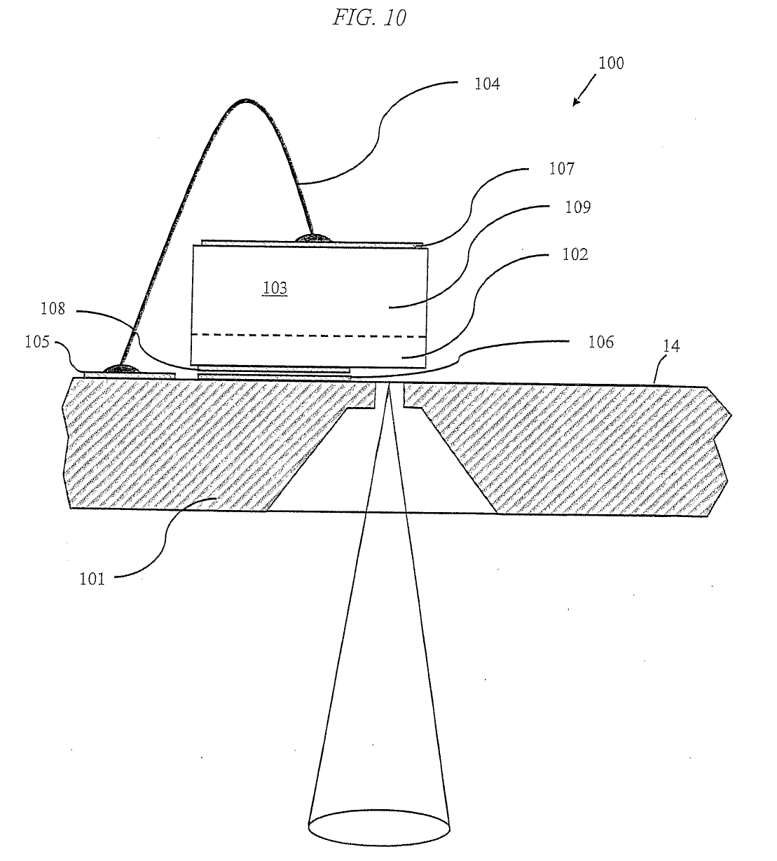

FIG. 10 is a schematic cross-sectional view of a surface-emitting optical device mounted on a carrier in inverted configuration illustrating a first arrangement for forming electrical contacts between the optical device and the carrier; and

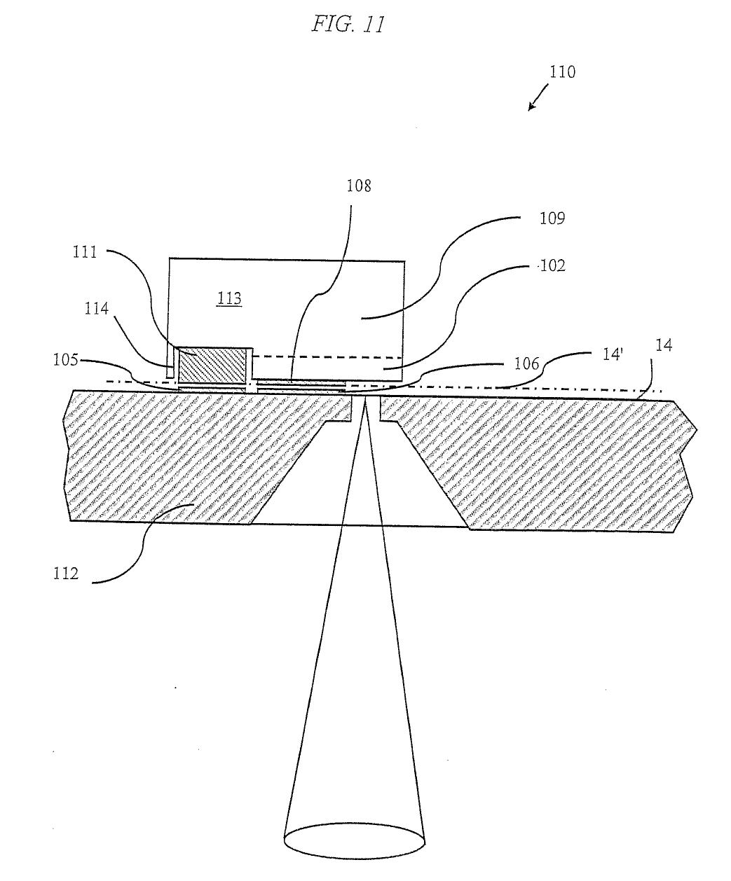

FIG. 11 is a schematic cross-sectional view of a surface-emitting optical device mounted on a carrier in inverted configuration illustrating a second arrangement for forming electrical contacts between the optical device and the carrier.

Throughout the present specification, the expression ‘surface-emitting’ optical device refers to the class of devices in which the emitting aperture of the device lies in a major surface rather than an edge of the device. Thereby, the optical axis of the output is transverse (and typically orthogonal) to the planes of the grown or deposited layers of the device. The expression ‘emission surface’ refers to the external surface of the device from which optical output emanates from an optical output aperture. The expression ‘aperture’ used in this context, as is conventional, refers to an optically confining medium from which optical radiation can emerge and not necessarily a physical ‘hole’ or void. The optical radiation of devices described may be in the visible and/or non-visible part of the spectrum.

It is often the case that LEDs and VCSELs are the preferred light source in an optical sub-assembly or module. The optical sub-assembly may require a single light source or a multiplicity of light sources. The multiplicity of light sources may be in the form of a single chip, monolithic array of light emitting devices or an array of discrete devices. The latter is often the case when an array of light sources emitting at a multiplicity of wavelengths is required.

In some optical sub-assembles, particularly those used in imaging optics systems, the distance from the emitting aperture of the LED or VCSEL to another key optical component in the sub-assembly, such as a lens, must be controlled with a high degree of accuracy. This situation is particularly pertinent in the case that the key optical element is a lens designed to expand the beam from the surface-emitting device.

Referring to FIG. 1, two top-emitting optical devices 12 and 13 are mounted, either using a solder or epoxy die attach process, onto a carrier or sub-mount 11. The expression ‘top-emitting’ is used to indicate that the confining aperture or cavity which defines an optical output plane is at the top external surface 15 or 16 of the devices as shown and the optical output 17 emerges from the face of the device remote from the substrate. The top surface 14 of the carrier or sub-mount 11 is, in general, a well defined mechanical reference surface and hence acts as an optical reference plane to which other components can be or must be accurately aligned. For a top-emitting device the position of the emitting aperture in relation to the reference plane 14 of the sub-mount, will depend upon the thickness of the device chip. The thickness of the chip is normally determined by a wafer lapping process which can typically achieve a given specified thickness to within ±10 μm.

As shown in FIG. 1, the two devices 12 and 13 have differing thicknesses and hence the distance from the reference plane of the top surface of the sub-mount 14 to the top external surfaces 15, 16 defining the optical output apertures is different for each device. In some high precision optical sub-assemblies the uncertainty and distribution in the relative displacement of the planes 15 and 16 from the optical reference plane 14 must be better than 1 micron and hence using conventional wafer lapping technology for the device fabrication is unacceptable. This problem is further exacerbated when it is necessary to create an array of discrete devices manufactured using differing material systems and which are derived from completely different manufacturing processes.

Two immediate prior art solutions are apparent. The first prior art solution is to manufacture the optical devices with chip thicknesses controlled to a high tolerance which incurs a high additional cost. The second prior art solution as represented in FIG. 2 is to fabricate the optical devices as bottom-emitting devices. The expression ‘bottom-emitting’ device refers to a device in which the confining optical aperture or cavity is at or near a bottom surface of the device (i.e. that closest to the substrate), the optical output 17 then being transmitted through a non-confining transparent substrate medium of the chip on which the devices are fabricated. In such a configuration, the displacement of the planes of the emission apertures, 23 and 24, of the source optical devices 21 and 22 with respect to the reference plane 14 of the sub-mount 11 is independent of the device chip thickness. This second approach is not appropriate for devices with a substrate that is highly absorbing at the emission wavelength of the device. For such devices, e.g. VCSELs having visible optical output in the red region of the spectrum and fabricated on gallium arsenide substrates, an alternative solution is to completely remove the absorbing substrate and replace it with one that is transparent. However this approach is expensive and prone to low yield.

The present invention is directed to achieving the desired control of the displacement of the emitting apertures to a carrier reference plane using devices of arbitrary chip thickness. In some circumstances, it is also highly desirable that the lateral alignment of the optical axes 18, 19 (see FIG. 1) of the emission apertures with respect to one another and/or with respect to other external components such as lenses and apertures is also precisely controlled. The mounting technology described herein also can achieve such alignment control at low cost.

With reference to FIG. 3, the reference plane defined by the surface 14 of the carrier or sub-mount 31 is also made substantially coincident with the planes 23, 24 of the output apertures of the surface-emitting devices 32, 33 by inverting top-emitting devices 32, 33 such that the optical output 17 is directed downwards toward the carrier 31. Thus, the surface 14 of the carrier 11 becomes both the mechanical and optical reference plane and the carrier 11 may be formed from materials which are routinely manufactured with high precision flat surfaces such as, but not exhaustively, copper, silicon, aluminium nitride or glass. For light emitting semiconductor devices such as LEDs and VCSELs, the emitting surface of the top-emitting device is also flat to a high precision and hence if this surface is bonded to the carrier 11 the displacement of the plane containing the emitting aperture of the device is accurately controlled and is independent of the actual chip thickness of the device.

To facilitate this inverted attachment, the carrier 31 is adapted to allow transmission of the optical output. In the arrangement of FIG. 3, the carrier 31 is made from a material which need not be optically transparent at the emission wavelength of the optical devices, e.g. silicon. Within this carrier 31 is formed a cavity 34 and membrane 36 using a standard silicon etch such as KOH, which etches preferentially along the crystal planes 35 of the silicon. Optical via-holes 37 are formed through the membrane 36, for example by etching through the membrane 36 using standard photolithographic silicon processing techniques to achieve a high degree of accuracy in terms of the diameters of the holes 37 and their separation.

The optical devices 32, 33 are ‘flip-chip’ mounted on the top surface 14 of the carrier 31, which is the reference plane. In other words, the top-emitting devices 32, 33 are inverted so that the emission surfaces are facing and mounted onto the reference surface 14 of the carrier 31 with the optical output apertures in overlying relation to the via-hole in the carrier. The expression ‘overlying’ is intended to indicate that two components are in sufficient axial alignment that they at least partially, and preferably entirely, share an optical path. The diameter of the holes 37 and the thickness of the membrane 36 are such that the optical devices 32, 33, once flip-chip mounted, have their optical output apertures laterally aligned to respective optical via-holes 37. The cavity 34 is preferably configured so that the side walls do not interfere with the beam 17 propagation. This is preferably effected by the cavity 34 having a tapered profile with its wide aspect more proximal to the back surface 38 of the carrier and its narrow aspect most proximal to the top or reference surface 14.

From FIG. 3 it is clear that the emission aperture planes 23 and 24 of the optical devices 32 and 33 are coincident with the flat reference surface 14 of the carrier 31 and that the displacement between these planes is independent of the optical device chip thickness. The reference surface 14 can therefore be used within an optical sub-assembly to accurately align additional optical elements such as lenses or apertures to this surface.

To achieve full operation of the optical devices it may be necessary to create metal contact layers on the carrier or sub-mount 31 to contact the emitting surface of the optical device and to use wire bonding to contact the opposing surface. Various methods and arrangements are possible as will be discussed later.

Although reference has been made to silicon as an ideal material from which to create a carrier or sub-mount, alternative sub-mount materials could also include copper, aluminium nitride or glass. Other materials may also be used.

FIG. 4 shows an assembly 40 having a carrier 41 manufactured from a material such as aluminium nitride in which the optical via holes 42 are formed as an integral part of the manufacture of the carrier and have a cross-sectional profile such that the slopes of the side-walls 43 of the optical via holes do not interfere with the beam propagation of the optical device 32, 33. In the case of the optical device being a single mode VCSEL, the beam divergence might be of the order 10 to 15 degrees from the beam axis and thus the slope of the side-walls 43 could be of a minimum of 20 degrees.

In a general aspect, it will be understood that the carrier 31, 41 has first and second opposing surfaces, the first surface comprising the reference plane or top surface 14 on which the optical devices 32, 33 are to be mounted. The second surface comprises a back surface 38 and one or more apertures extend between the reference surface and the back surface. The aperture may comprise a larger cavity extending most of the way from the back surface 38 to the reference surface 14, with one or more smaller via-holes extending through the remaining thickness of the carrier. Alternatively, the aperture may have one or more discrete apertures that extend right the way through the carrier from the back surface to the reference surface. The carrier aperture or apertures generally may have a tapered profile.

It is often the case that additional optical elements must be aligned with the optical devices 32, 33 such as lenses, apertures or steering mirrors. Generally, these must be accurately aligned both axially and longitudinally with respect to the emitting apertures of the optical devices. Such additional optical elements generally are provided to in some way condition or optically process the output beam of an associated optical device, particularly to control beam aspect or shape. FIG. 5 reveals how a sub-mount or carrier 31 may be modified to enable it to be accurately mounted on a substrate 55 to which is also mounted additional optical elements such as lenses 54.

FIG. 5 shows a substrate 55 which is formed from a material such as silicon in which location features such as recesses 52, 53 and a cavity 56 are formed using lithographic and etch processes achieving an alignment tolerance between the features of the order of 1 micron and feature depths maintained to an accuracy of a few microns. The carrier 31 may also contain location features that cooperate with the location features of the substrate 55. In the preferred embodiment shown, the carrier location features comprise a stepped edge or recess 57 that keys into the recess 53 of the substrate 55.

It will be recognised that any suitable shape of location feature may be used on the substrate 55 that is able to cooperate with a corresponding location feature on the carrier 31 to assist or guide correct positioning of the substrate 55 and carrier 31 relative to one another. These location features could include recesses and corresponding teeth having rectangular or angled/tapered profiles. Such location features provide physical guidance and/or physical engagement structures for locating the substrate and carrier against one another in a predetermined relationship.

The location features described above are a specific form of more general alignment features. The expression ‘alignment features’ is intended to also encompass features that only provide visual or optical guidance to correct positioning of the substrate and carrier in relation to one another, such as visual marks that assist in correct placement during a bonding operation. These optical guidance features need not necessarily provide physical engagement structures as shown in FIG. 5. The expression ‘optical guidance feature’ is intended to encompass both features visible to the human eye and those that might be only machine readable.

A recess 56 is provided in the substrate 55 so that the optical devices 32, 33 can be inverted and mounted on the substrate 31 such that the reference surface 14 of the carrier 31 and top surface 58 of the substrate 55 are either co-planar or in close proximity determined by the etch depth of the location features 53, 57 and to an accuracy determined by the accuracy to which the etch depth of the location features can be formed. Additional optical elements such as the diverging lenses 54 can be formed from injected moulded plastic or other suitable materials on or integral with an optical sub-mount 51 which also includes location features such as projections 59 that cooperate with the features 52 implemented in the substrate 55, thus achieving a high degree of lateral (axial) and longitudinal alignment with the optical devices 32, 33. In such an assembly 50 as shown in FIG. 5, it will be seen that the quality of alignment of the optics is independent of the thickness of the optical device chips 32, 33.

Thus, it can be seen that more generally the arrangement provides for alignment features that assist in the positioning of the optical device in registration with the carrier apertures, and also in registration with additional optical elements such as lenses 54.

FIG. 6 shows an alternative arrangement of carrier 31, substrate 55 and lens 61 such that alignment features 62 on the substrate 55 are implemented using a lithographic deposition technique such as the deposition of glass or polymer. Corresponding alignment features 62a are then etched into the top (reference) surface of the carrier 31. In this instance when the carrier 31 is inverted, aligned to the substrate 55 and bonded, the top surface 58 of the substrate 55 and the reference surface 14 of the carrier 31 are co-planar and laterally located to a high degree of accuracy.

FIG. 6 shows an assembly 60 in which an additional optical element such as lens array 61 is aligned to the features that form the optical via-holes in the carrier. In this arrangement, the additional optical element is mounted within the aperture cavity 34 in the carrier 31. In such an assembly, the quality of alignment of the optics is independent of the thickness of the optical device chips.

FIG. 7 shows an assembly 70 in which an additional optical element, such as a lens 71, is formed or attached directly onto an optical device 72, 73, as an integral part of the optical device fabrication, e.g. as a surface feature or surface mounted feature. In this arrangement, the additional optical elements 71 each extend into the respective apertures of the carrier 31. In such an assembly 70 the quality and alignment of the optics is independent of the thickness of the optical device chips 72, 73.

FIG. 8 shows an assembly 80 in which the carrier 81 is made from a transparent material such as quartz glass. Metal bond pads 85 are deposited on the surface of the carrier 81 for bonding the optical devices 32, 33 to the carrier 81, and also for attaching wire bonds 84 to electrical contacts 86 formed on the back surface of the optical devices 32, 33. On the back surface 87 of the transparent substrate of the carrier 81, an additional optical element in the form of one or more lenses or a micro-lens array 82 can be etched into the material using standard photoresist flow technology. In this way, the additional optical element 82 can form part of the carrier bulk material. Alignment of the lens or lens array 82 to front-side metal pattern 85 can be better than ±1 micron using standard double sided aligner technology. Furthermore the glass substrate can be coated with an anti-reflective coating 83 to reduce back reflections into the light-source. In such an assembly the quality and alignment of the optics is independent of the thickness of the optical device chips.

It will be recognised that in the assembly 80 of FIG. 3, the ‘aperture’ extending through the carrier 81 is effectively an optical aperture 88 through the medium of the carrier bounded by, for example, the metallization of bond pads 85. Depending on the nature of the antireflection coating 83 (e.g. if bidirectional), the optical aperture may also be photolithographically defined breaks (not shown) in the antireflection coating laterally aligned with the emission apertures of the optical devices 32, 33. Preferably the optical aperture defined by breaks in the metallization 85 and/or antireflection coating 83 is of similar size (i.e. only slightly larger than) the beam width 17 at the point it emerges from the emission aperture of the optical device 32 so that scattering, refraction or deflection into the substrate at oblique angles is reduced or inhibited.

FIG. 9 shows an arrangement in which two or more surface emitting devices 91, 92 are disposed onto the reference surface 14 defined by a substrate 55, to emit optical radiation beams 17. One or more additional optical elements, such as lens array 54, are defined in or on, or mounted to, an optical sub-unit 51. This optical sub-unit 51 is also mounted to the reference surface 14 of the substrate 55, thus ensuring that there is exact longitudinal (axial) relationship along the beam axes between the optical devices 91, 92 and the additional optical elements such as lenses 54. The optical sub-unit 51 can also be laterally registered (i.e. orthogonal to the beam axis) with the optical devices 91, 92 by using location features such as recesses 52 and corresponding alignment features 52a similar to those described in connection with FIGS. 5 and 6. This arrangement is particularly useful where the emission aperture plane of the optical devices 91, 92 is either known in relation to the reference plane 14 or not critical to the placement of the additional optical elements 54. This arrangement is also useful where the lateral alignment between the optical devices 91, 92 and the additional optical elements 54 is critical as both can be registered to the location features 52, 52a.

Any suitable number of surface emitting optical devices can be mounted in this way in registration with the optical sub-unit and the optical elements mounted thereon. This can be useful, for example, where a lens array must be mounted in precise alignment with a number of optical devices so that the additional optical elements are in overlying relation to the emitting apertures of the optical devices.

The arrangement of FIG. 9 also offers a further advantageous feature. Each optical device 91, 92 may include a lens arrangement 93 mounted on, or forming an integral part of, the emission aperture. This lens arrangement 93 may be a converging or diverging lens adapted to modify the output beam of the device to a substantially parallel beam 94, i.e. with substantially zero divergence. The additional optical element 54 then modifies the beam 94 to a desired diverging or converging form of beam 17. This arrangement provides the advantage that the sensitivity to variation in longitudinal separation of the emission surface of device 91 or 92 from a respective optical element 54 is diminished or substantially eliminated since little or no variation in lateral beam profile occurs in parallel beams 94. Thus, significant variations in thicknesses of optical devices 91, 92 will have little or no effect on the final profile of beam 17.

Thus, in a general aspect, it will be recognised that the optical sub-unit 51 may provide a plurality of optical elements each adapted to condition a parallel output beam from a respective one of a plurality of optical devices having emission apertures at varying distances from the optical sub-unit or reference plane on which they are mounted.

Various methods and arrangements may be used to effect electrical connection of the surface emitting optical devices to other components. In preferred arrangements, electrical connection is made by way of the carrier, e.g. carrier 81 as shown in FIG. 8. Two such arrangements are shown in FIGS. 10 and 11 respectively.

FIG. 10 shows an assembly 100 in which a top-emitting optical device 103 has been ‘flip-chip’ mounted onto the top (reference) surface 14 of a carrier 101. The carrier 101 includes a cavity and via-hole as previously described in relation to FIGS. 3 and 4. The device 103 has a first electrode or contact 108 on its emission surface and a second electrode or contact 107 on the bottom surface of the substrate 109. (It will be understood that the device is inverted in FIG. 10.) The substrate may, for example, be an n-type substrate allowing electrical connection to the device disposed in p-type semiconductor layers 102.

Carrier 101 includes a pair of electrical contacts 105, 106 disposed on its reference surface 14. A first one of the carrier contacts 106 may be bonded directly with the first electrode 108 on the optical device during the flip-chip mounting process. A second one of the carrier contacts 105 may be electrically connected to the second (i.e. substrate) electrode 107 by a wire bond 104 using established wire bond techniques. Thus, it will be recognised that the optical device 103 is both electrically and mechanically bonded to the carrier 101 by at least one corresponding pair of electrical contacts 106, 108 respectively on the carrier 101 and device 103.

FIG. 11 shows another assembly 110 in which a top-emitting optical device 113 has been ‘flip-chip’ mounted onto the top (reference) surface 14 of a carrier 112. The carrier 112 includes a cavity and via-hole as previously described in relation to FIGS. 3 and 4. The device 113 has a first electrode or contact 108 on its emission surface and a second electrode or contact 111 on the emission surface. In this instance, the second electrode 111 may make electrical contact with the substrate 109 of the device by etching a contact hole 114 past the p-type semiconductor layers 102 and through to the n-type substrate 109.

Carrier 112 includes a pair of electrical contacts 105, 106 disposed on its reference surface 14. A first one of the carrier contacts 106 may be bonded directly with the first electrode 108 on the optical device and a second one of the carrier contacts 105 may be bonded directly with the second electrode 111 during the flip-chip mounting process. Thus, it will be recognised that the optical device 113 is both electrically and mechanically bonded to the carrier 101 by at least two corresponding pairs of electrical contacts 106, 108 and 105, 111 respectively on the carrier 112 and device 113.

Typically, the electrical contacts 105, 106 are sufficiently thin layers of material that the surfaces thereof are, for all practical purposes, co-planar with the reference surface 14 of the carrier 112. However, it will be understood that where electrical contacts of significant thickness are formed, the reference surface of the carrier could be effectively defined by the surfaces of the contacts 105, 106 themselves, as indicated at 14′, i.e. slightly offset from the main surface of the carrier 112.

Both the first electrode 108 and second electrode 111 preferably have co-planar surfaces so that they can be bonded to co-planar contacts 105, 106 on the reference surface 14 of the carrier 112. However, it will be understood that if the electrodes 108 and 111 are not co-planar, corresponding relief of one of the contacts 105 or 106 could accommodate such lack of co-planarity.

The arrangement of FIG. 11 offers an advantage of avoiding the need for a wire bonding operation.

Other embodiments are within the scope of the accompanying claims.

1. An optical emitter assembly comprising:
a surface-emitting optical device having an emission surface providing an optical output aperture;
a carrier having first and second opposing surfaces, the first surface being a reference surface on which the optical device is mounted by its emission surface and the second surface being a back surface, the carrier having an aperture extending between the reference and back surfaces;
the optical device being positioned on the reference surface such that its optical output aperture is in overlying relation with the carrier aperture to direct optical radiation therethrough.

2. The assembly of claim 1 further including
a second surface-emitting optical device having an emission surface providing an optical output aperture, the second device being mounted to the carrier by its emission surface,
the carrier having a second aperture extending between the reference and back surfaces, the second optical device being positioned on the reference such that its optical output aperture is in overlying relation with the carrier second aperture to direct optical radiation therethrough.

3. The assembly of claim 1 in which the emission surface of the optical device has plural optical output apertures, each optical output aperture being in overlying relation to a carrier aperture.

4. The assembly of claim 1 in which the carrier aperture comprises a tapered cavity having its wide aspect most proximal to the back surface and its narrow aspect most proximal to the reference surface.

5. The assembly of claim 4 in which the carrier aperture further includes one or more via holes extending between the reference surface and the tapered cavity.

6. The assembly of claim 5 in which plural ones of the via holes are separated by a membrane.

7. The assembly of claim 4 in which the tapered cavity is etched preferentially along crystallographic planes of the carrier material.

8. The assembly of claim 1 in which the reference surface of the carrier includes alignment features to assist in the positioning of the optical device in registration with the carrier aperture.

9. The assembly of claim 1 further including at least one additional optical element mounted to the carrier for conditioning the optical output of the optical device.

10. The assembly of claim 9 in which the additional optical element is attached within a cavity forming part of the carrier aperture.

11. The assembly of claim 10 in which the additional optical element includes a lens array, each lens having its optical axis in alignment with at least one carrier aperture and a corresponding optical output aperture of an optical device mounted to the carrier.

12. The assembly of claim 1 further including at least one additional optical element for conditioning the optical output of the optical device, the additional optical element and assembly being attached to a common substrate.

13. The assembly of claim 12 in which the common substrate defines a common reference plane for the reference surface of the carrier and the additional optical element.

14. The assembly of claim 1 further including an additional optical element mounted to the emission surface for conditioning the optical output of the device, the additional optical element extending into the carrier aperture beyond the reference surface.

15. The assembly of claim 1 further including at least one additional optical element forming part of the carrier bulk material, for conditioning the optical output of the optical device.

16. The assembly of claim 1 in which the carrier aperture comprises a void.

17. The assembly of claim 1 in which the carrier aperture comprises a region of bulk material transparent to optical radiation.

18. The assembly of claim 1 in which the carrier includes a first and a second electrical contact disposed on the reference surface and the optical device includes at least a first electrode disposed on the emission surface, the first electrical contact and the first electrode being both electrically and mechanically coupled to one another by the opposing relation of the reference surface and the emission surface.

19. The assembly of claim 18 in which the optical device includes a second electrode disposed on the emission surface, the second electrical contact and the second electrode being both electrically and mechanically coupled to one another by the opposing relation of the reference surface and the emission surface.

20. The assembly of claim 18 in which the optical device includes a second electrode disposed on a substrate surface, the second electrical contact and the second electrode being electrically coupled to one another by wire bond.

21. An optical emitter assembly comprising:
at least two surface-emitting optical devices each having an emission surface providing an optical output aperture;
a carrier having first and second opposing surfaces, the first surface being a reference surface on which the optical devices are mounted by their respective emission surfaces and the second surface being a back surface, the carrier having an optical transmission path extending between the reference and back surfaces suitable for transmission of optical radiation from the optical devices;
at least one additional optical element disposed on the back surface of the carrier, the optical devices being positioned on the reference surface such that their optical output apertures are in overlying relation with a respective additional optical element such that the respective additional optical element is in the optical paths of optical emissions from the optical devices.

22. The assembly of claim 21 in which the at least one additional optical element is an array having separate portions, each portion positioned to receive radiation from a corresponding one of the surface-emitting optical devices.

23. The assembly of claim 21 in which the at least one additional optical element is an array of discrete optical elements, each element positioned to receive radiation from a corresponding one of the surface-emitting optical devices.

24. The assembly of claim 21 in which the at least one additional optical element is a lens integrally formed in the bulk material of the carrier.

25. The assembly of claim 21 in which the at least two surface-emitting optical devices have different substrate thicknesses.

26. The assembly of claim 21 in which the carrier includes a first and a second electrical contact disposed on the reference surface and the optical device includes at least a first electrode disposed on the emission surface, the first electrical contact and the first electrode being both electrically and mechanically coupled to one another by the opposing relation of the reference surface and the emission surface.

27. The assembly of claim 26 in which the optical device includes a second electrode disposed on the emission surface, the second electrical contact and the second electrode being both electrically and mechanically coupled to one another by the opposing relation of the reference surface and the emission surface.

28. The assembly of claim 26 in which the optical device includes a second electrode disposed on a substrate surface, the second electrical contact and the second electrode being electrically coupled to one another by wire bond.

29. An optical emitter assembly comprising:
a surface-emitting optical device having an emission surface providing an optical output aperture and a back surface opposite to the emission surface;
a carrier having a reference surface on which the optical device is mounted by its back surface;
an additional optical element for conditioning the optical output of the optical device, the additional optical element being mounted on or formed in an optical sub-unit;
the optical sub-unit being mounted on the reference surface such that the additional optical element is in overlying relation with the optical output aperture of the optical device so as to receive optical radiation therefrom.

30. The assembly of claim 29 further including a second surface-emitting optical device having an emission surface providing an optical output aperture and a back surface opposite to the emission surface, the second optical device being mounted by its back surface to the reference surface of the carrier, and in which the optical sub-unit further includes a second additional optical element for conditioning the optical output of the second optical device, the second additional optical element being mounted on or formed in the optical sub-unit such that the second additional optical element is in overlying relation with the optical output aperture of the second device so as to receive optical radiation therefrom.

31. The assembly of claim 29 in which the optical sub-unit and/or carrier has at least one alignment feature to assist the positioning of the optical sub-unit in registration with the optical device.

32. The assembly of claim 31 in which the alignment feature comprises a protrusion and corresponding recess respectively in the carrier reference surface and the optical sub-unit or vice versa.

33. The assembly of claim 30 in which the first and second optical devices have different thicknesses of substrate.

34. The assembly of claim 30, in which each of the first and second optical devices includes a lens element for conditioning the output of the respective device into a substantially parallel beam.

35. The assembly of claim 34 in which each additional optical element is adapted to condition the respective substantially parallel beam from the first and second optical devices to a non-parallel final beam profile.

36. The assembly of claim 35 in which the non-parallel final beam profiles are substantially insensitive to the axial separation of the respective emission surfaces and the optical sub-unit.

37. A method of mounting a surface-emitting optical device onto a carrier, the optical device having an emission surface providing an optical output aperture, comprising the steps of:
forming a carrier having first and second opposing surfaces, the first surface being a reference surface on which the optical device is to be mounted and the second surface being a back surface opposite thereto;
forming a carrier aperture extending between the reference and back surfaces;
bonding the optical device by its emission surface to the reference surface of the carrier such that its optical output aperture is in overlying relation with the carrier aperture to direct optical radiation therethrough.

38. A method of mounting surface-emitting optical devices onto a carrier, the optical devices each having an emission surface providing an optical output aperture and a back surface opposite to the emission surface, comprising the steps of:
forming a carrier having first and second opposing surfaces, the first surface being a reference surface on which the optical devices are to be mounted and the second surface being a back surface, the carrier having an optical transmission path extending between the reference and back surfaces suitable for transmission of optical radiation from the optical devices and the carrier including an additional optical element for conditioning the output of the optical devices;
bonding the optical devices by their respective emission surfaces to the reference surface of the carrier, the optical devices being positioned on the reference surface such that their optical output apertures are in overlying relation with a respective additional optical element such that the respective additional optical element is in the optical paths of optical emissions from the optical devices.

39. A method of mounting a surface-emitting optical device onto a carrier, the optical device having an emission surface providing an optical output aperture and a back surface opposite to the emission surface, comprising the steps of:
forming a carrier having a reference surface;
bonding the optical device, by its back surface, to the reference surface;
forming an additional optical element in or on an optical sub-unit, for conditioning the optical output of the optical device;
mounting the optical sub-unit onto the reference surface such that the additional optical element is in overlying relation with the optical output aperture of the optical device so as to receive optical radiation therefrom.

40. (canceled)
